(19) United States
(12) Patent Application Publication
(10) Pub. No.: US 2004/0029389 A1
(43) Pub. Date: Feb. 12, 2004

(54) Method of forming shallow trench isolation structure with self-aligned floating gate

(75) Inventor: Wen-Shun Lo, Hsinchu (TW)

Correspondence Address: LOWE HAUPTMAN GOPSTEIN GILMAN & BERNER, LLP, 1700 Diagonal Road, Suite 310, Alexandria, VA, 22314, US

(73) Assignee: WINBOND ELECTRONICS CORPORATION

(21) Appl. No.: 10/212,226

(22) Filed: Aug. 6, 2002

(51) Int. Cl. H01L 21/311

(52) U.S. Cl. 438/694

(57) ABSTRACT

A method for fabricating a shallow trench isolation structure with self-aligned floating gates is described. The method utilizes a sacrificial layer to form an isolation trench with ladder profile on a substrate. A tunnel oxide layer, a floating gate polysilicon layer and a patterned silicon nitride layer as a hard mask layer are sequentially formed on the substrate. The floating gate polysilicon layer is etched up to the tunnel oxide layer and the silicon nitride layer serves as a hard mask. The sacrificial layer is formed around the floating gate polysilicon layer in situ. After etching the substrate for forming the trench, the sacrificial layer is removed. Heating the trench forms a liner oxide layer and then depositing a silicon dioxide layer fills the trench. The method according to the invention reduces the voids in the trench and improves the yield of mass production.

### FIELD OF THE INVENTION

The present invention relates generally to the fabrication of semiconductor memory devices and especially to the fabrication of a self-aligned floating gate using the Shallow Trench Isolation process.

### BACKGROUND OF THE INVENTION

In order to reduce the memory cell size for a low bit cost, Shallow Trench Isolation (STI) has been applied to the flash memory cell. It is inevitable that the gate oxide breakdown voltage is degraded by a field enhancement effect when a gate overlaps the shallow trench corner. In order to resolve this issue, a self-aligned floating gate above the STI structure was proposed. In this structure, the floating gate and the isolation trench are etched using the same mask and are self-aligned with each other, such that an overlap between the gate and the shallow trench corner will not occur. As a result, the yield of the gate oxide breakdown is improved.

But the self-aligned floating gate above the Shallow Trench Isolation structure still has some problems. In this structure, the tunnel oxide layer with a thickness of about 100 Å exists between the floating gate polysilicon layer and the substrate of crystalline silicon. After the liner oxide layer is formed within the trench using thermal oxidation, the portion of the floating gate polysilicon layer and the substrate of crystalline silicon oxidized protrudes relative to the tunnel oxide layer around the trench. As a result, a re-entrant profile appears around the tunnel oxide layer and small voids easily form during silicon dioxide deposition to fill the trench.

FIGS. 1A to 1D are the schematic, cross-sectional diagrams showing processes for fabricating the STI structure with the self-aligned floating gate. As depicted in FIG. 1A, a substrate 100 is provided. A tunnel oxide layer 102, a floating gate polysilicon layer 104 and a patterned silicon nitride layer 106 as a hard mask layer are sequentially formed on the substrate 100. A trench 110 is formed by an etching process through the opening 108 of the patterned silicon nitride layer 106, as shown in FIG. 1B. The FIG. 1C shows a liner layer 112 formed from a thermal oxide of the silicon. There is a re-entrant profile near floating gate polysilicon layer 104. After that, as shown in FIG. 1D, the silicon dioxide layer 116 is formed by filling the inner side of the liner layer 112 and voids 114 are formed. The voids 114 may downgrade the electric performance of the semiconductors and reduce the yield of the semiconductors. Therefore, how to solve the problem of small voids existing near the tunnel oxide region in the trench is important to semiconductor manufacture.

### SUMMARY OF THE INVENTION

The present invention provides a method for fabricating a shallow trench isolation structure with self-aligned floating gates to reduce and improve the problem of small voids existing near the tunnel oxide region in the trench.

To achieve these and other advantages and in accordance with the purpose of the invention, the method for fabricating a shallow trench isolation structure with self-aligned floating gates comprises the following processes. The method utilizes a sacrificial layer to form an isolation trench with a ladder profile on a substrate. A tunnel oxide layer, a floating gate polysilicon layer and a patterned silicon nitride layer as a hard mask layer are sequentially formed on the substrate. The floating gate polysilicon layer is etched up to the tunnel oxide layer. The silicon nitride layer serves as a hard mask in the etching process and the sacrificial layer is formed around the floating gate polysilicon layer in situ. The sacrificial layer is removed after etching the substrate for forming the trench. Heating the trench may form a liner oxide layer on the isolation trench. Finally, a silicon dioxide layer is deposited and fills the trench. The invention employs the etching recipe in situ to oxidize and deposit the polymer on the sidewall of the floating gate polysilicon layer, and remove the polymer and oxide film to form the ladder profile of the sidewall in the isolation trench. The profile can be improved and small voids can be avoided, and therefore the semiconductor electrical performance is enhanced.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIGS. 1A to 1D are the schematic, cross-sectional diagrams showing processes for fabricating the STI structure with the self-aligned floating gate as disclosed in prior art; and

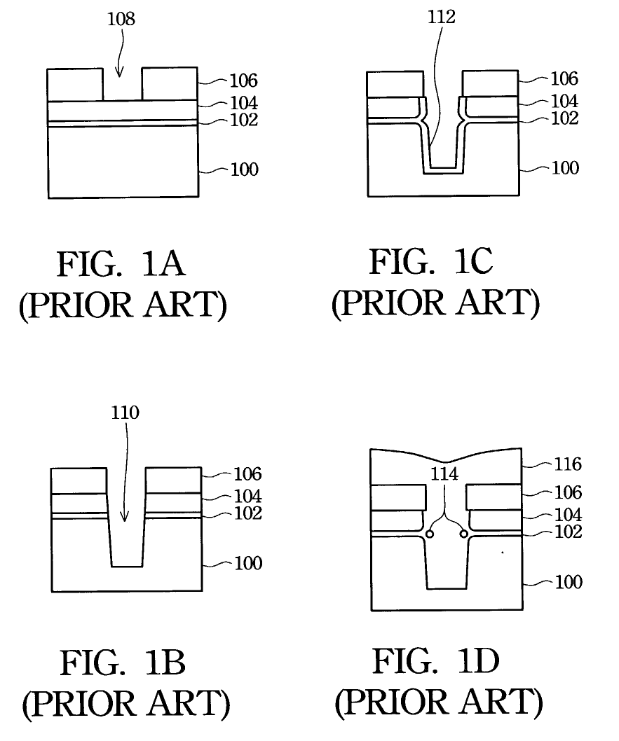

FIGS. 2A to 2F are the schematic, cross-sectional diagrams showing processes for fabricating the STI structure with the self-aligned floating gate according to the preferred embodiment of the present invention.

### DETAILED DESCRIPTION OF THE PREFERRED EMBODIMENT

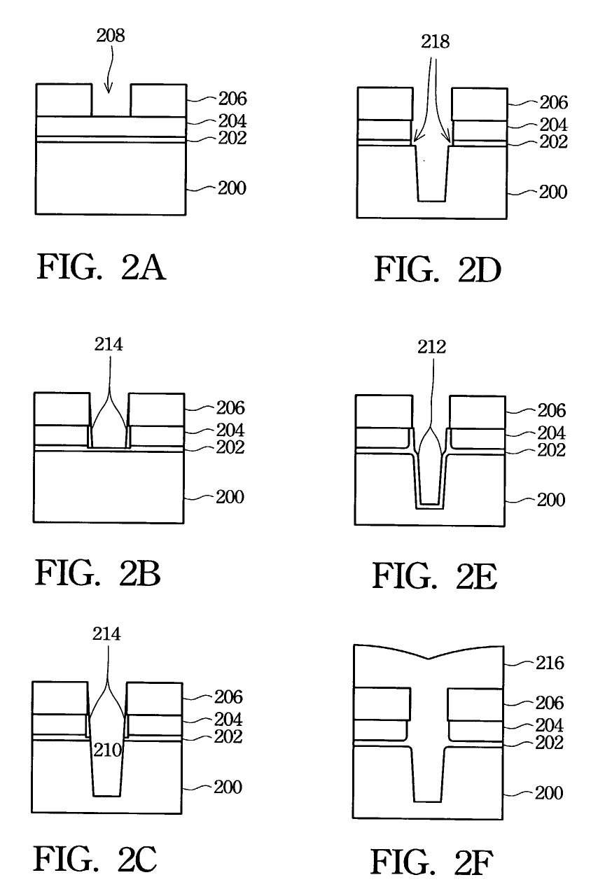

FIGS. 2A to 2F are schematic, cross-sectional diagrams showing processes for fabricating the STI structure with the self-aligned floating gate according to the preferred embodiment of the present invention. Referring to FIG. 2A, a tunnel oxide layer 202, a floating gate polysilicon layer 204, and a patterned silicon nitride layer 206 serving as a hard mask with a opening 208 are formed in sequence on a substrate 200. The tunnel oxide layer 202 is about 80 Å to 120 Å thick, the floating gate polysilicon layer 204 is about 400 Å to 1000 Å thick, and the patterned silicon nitride layer 206 is about 1500 Å to 2500 Å thick. The step of forming the opening 208 includes dielectric dry etching.

Referring to FIG. 2B, using the patterned silicon nitride layer 206 as a hard mask, the floating gate polysilicon layer 204 is etched, and the etching process is stopped on the tunnel oxide layer 202. While etching the floating gate polysilicon layer 204, the etching recipe is tuned to have a very high selectivity of silicon to oxide and, at the same time, the sidewall of the trench in the floating gate polysilicon layer 204 is oxidized and deposited with polymer to form a sacrificial layer 214. The sacrificial layer 214 can be controlled to a thickness of about 50 Å to 300 Å by the etching conditions. The etching recipe contains gaseous Cl₂, HBr, and O₂ using a poly etcher, e.g., DPS (Applied Materials) or 84DD (TEL). Preferred process parameters of the DPS etcher are as follows:

the pressure: 4-10 mT,

the source power: 250-500 W,

the bias power: 90-180 W,

the flow rate of Cl₂: 0-30 sccm,

the flow rate of HBr: 100-200 sccm, and

the flow rate of O₂: 10-50 sccm.

Preferred process parameters of the 84DD etcher are as follows:

the pressure: 10-30 mT,

the source power: 400-800 W,

the flow rate of Cl₂: 0-50 sccm,

the flow rate of HBr: 60-150 sccm, and

the flow rate of O₂: 10-50 sccm.

After etching the floating gate layer 204 and the substance 200, the isolation trench 210 is formed, as showed in FIG. 2C. The isolation trench 210 is about 2500 Å to 4000 Å deep. The etching recipe contains gaseous Cl₂, HBr, and O₂ using a poly etcher, e.g., DPS (Applied Materials) or 84DD (TEL). Preferred process parameters of the DPS etcher are as follows:

the pressure: 4-10 mT,

the source power: 250-500 W,

the bias power: 90-180 W,

the flow rate of Cl₂: 10-50 sccm,

the flow rate of HBr: 100-200 sccm, and

the flow rate of O₂: 0-30 sccm.

Preferred process parameters of the 84DD etcher are as follows:

the pressure: 10-30 mT,

the source power: 400-800 W,

the flow rate of Cl₂: 20-60 sccm,

the flow rate of HBr: 60-150 sccm, and

the flow rate of O₂: 0-30 sccm.

After forming isolation trench 210, ashing and wet cleaning are subsequently performed, and then the sacrificial layer 214 and the thin oxidized layer on the sidewall of the floating gate polysilicon layer 204 are removed. A little ladder profile 218 is formed on the sidewall of the isolation trench 210, as shown in FIG. 2D.

Referring to FIG. 2E, a liner oxide layer 212, which is about 100 Å to 300 Å thick, is formed on a sidewall of the isolation trench 210. The liner oxide layer 212 meets the tunnel oxide layer 202. The process of forming the liner oxide layer 212 may utilize a thermal oxidation process.

Referring to FIG. 2F, a silicon dioxide layer 216 is deposited on the patterned silicon nitride layer 206 and fills the inside of the liner oxide layer 214 of the isolation trench 210. A high-density plasma chemical vapor deposition process is applied to deposit the silicon dioxide layer 216. Due to the improvement of the profile around the sidewall of the isolation trench 210, small voids near the tunnel oxide layer 202 can be easily avoided.

The invention uses the etching technique to in situ oxidize and deposit the polymer on the sidewall of the floating gate, and remove the polymer and oxide film to form the ladder profile of the sidewall of the isolation trench before liner oxide formation. As a result, the re-entrant profile is prevented after the oxide liner formation and small voids can be avoided when the silicon dioxide deposition fills the isolation trench.

As is understood by a person skilled in the art, the foregoing preferred embodiments of the present invention are illustrative of the present invention rather than limiting of the present invention. It is intended that various modifications and similar arrangements be included within the spirit and scope of the appended claims, the scope of which should be accorded the broadest interpretation so as to encompass all such modifications and similar structures.

What is claimed is:

1. A method for fabricating a shallow trench isolation structure with self-aligned floating gates, the method comprising the steps of:
providing a substrate with a tunnel oxide layer, a floating gate polysilicon layer and a patterned silicon nitride layer thereon in sequence;
etching the floating gate polysilicon layer up to the tunnel oxide layer with the patterned silicon nitride layer serving as a hard mask layer and in situ forming a sacrificial layer on and around the floating gate polysilicon layer;
etching the substrate to form a trench;
removing the sacrificial layer;
heating the trench to form a liner oxide layer; and
depositing a silicon dioxide layer to fill the trench.

2. The method according to claim 1, wherein the tunnel oxide layer is about 80 Å to 120 Å thick.

3. The method according to claim 1, wherein the floating gate polysilicon layer is about 400 Å to 1000 Å thick.

4. The method according to claim 1, wherein the patterned silicon nitride layer is about 1500 Å to 2500 Å thick.

5. The method according to claim 1, wherein the sacrificial layer is formed by polymers and is about 50 Å to 300 Å thick.

6. The method according to claim 1, wherein the step of removing the sacrificial layer utilizes an ashing process and a wet cleaning process.

7. The method according to claim 1, wherein the silicon dioxide layer is deposited in a high-density plasma chemical vapor deposition process.

8. The method according to claim 1, wherein the liner oxide layer is formed by a thermal oxidation process and is about 100 Å to 300 Å thick.

9. The method according to claim 1, wherein the trench is formed with a ladder profile and is about 2500 Å to 4000 Å thick.

10. A method for fabricating a shallow trench isolation structure with self-aligned floating gates, the method comprising the steps of:
(1) providing a substrate with a tunnel oxide layer, a floating gate polysilicon layer and a patterned silicon nitride layer thereon in sequence;
(2) etching the floating gate polysilicon layer up to the tunnel oxide layer with the patterned silicon nitride layer serving as a hard mask layer and forming a sacrificial layer on and around the floating gate polysilicon layer;
(3) etching the substrate to form a trench;
(4) ashing the sacrificial layer;
(5) cleaning the trench;
(6) heating the trench to form a liner oxide layer; and
(7) depositing a silicon dioxide layer to fill the trench.

11. The method according to claim 10, wherein steps (2) to (4) utilize a poly etcher in situ continually.

12. The method according to claim 10, wherein the tunnel oxide layer is about 80 Å to 120 Å thick.

13. The method according to claim 10, wherein the floating gate polysilicon layer is about 400 Å to 1000 Å thick.

14. The method according to claim 10, wherein the patterned silicon nitride layer is about 1500 Å to 2500 Å thick.

15. The method according to claim 10, wherein the sacrificial layer is formed by polymers and is about 50 Å to 300 Å thick.

16. The method according to claim 10, wherein step (5) utilizes a wet cleaning process to clean the trench.

17. The method according to claim 10, wherein the silicon dioxide layer is deposited in a high-density plasma chemical vapor deposition process.

18. The method according to claim 10, wherein the liner oxide layer is formed by a thermal oxidation process and is about 100 Å to 300 Å thick.

19. The method according to claim 10, wherein the trench has a ladder profile and is about 2500 Å to 4000 Å thick.
